(19) United States
(12) Patent Application Publication
(10) Pub. No.: US 2025/0283933 A1
(43) Pub. Date: Sep. 11, 2025

(54) ELECTRICAL CIRCUIT ARRANGEMENT AND METHOD FOR INSULATION MEASUREMENT ON A BATTERY ELECTRIC VEHICLE

(71) Applicant: SMA Solar Technology AG, Niestetal (DE)

(72) Inventors: Thomas Wappler, Guxhagen (DE); Klaus Rigbers, Göttingen (DE)

(21) Appl. No.: 19/219,233

(22) Filed: May 27, 2025

Related U.S. Application Data
(63) Continuation of application No. PCT/EP2023/087086, filed on Dec. 20, 2023.

(30) Foreign Application Priority Data
Dec. 20, 2022 (DE) 10 2022 134 131.3

(51) Int. Cl. G01R 31/14; B60L 58/16; G01R 31/00; G01R 31/52

(52) U.S. Cl. CPC G01R 31/14; B60L 58/16; G01R 31/006; G01R 31/52; B60L 2210/30

(57) ABSTRACT

The application discloses an arrangement/method for insulation measurement on an electric vehicle (EV). The arrangement is configured to be connected to a battery of the EV via EV terminals. The arrangement has a power converter with AC terminals for connecting to an AC grid and DC terminals. A first DC terminal is connectable to a first EV terminal via a first DC switch and a second DC terminal is connectable to a second EV terminal via a second DC switch or via a parallel circuit composed of the second DC switch and a third DC switch. The arrangement is configured to, when the power converter and the AC grid are connected: connect one of the DC terminals to the corresponding EV terminal by closing one of the DC switches, set a DC voltage at the DC terminals by clocking the power converter, and perform the insulation measurement.

### REFERENCE TO RELATED APPLICATIONS

This Application is a Continuation of International Application number PCT/EP2023/087086, filed on Dec. 20, 2023, which claims the benefit of German Application number 10 2022 134 131.3, filed on Dec. 20, 2022. The contents of the above-referenced Patent Applications are hereby incorporated by reference in their entirety.

### FIELD

The disclosure relates to an electrical circuit arrangement and to a method for insulation measurement on an electric vehicle (EV), for example, a battery electric vehicle.

### PRIOR ART

It is known to charge an electric vehicle (EV), also called a battery electric vehicle (BEV for short), with electrical power from an AC network using a charging device. The AC network can, for example, be an electricity supply network. A charging device may comprise an electrical circuit arrangement with an all-pole AC disconnection point for the AC terminals with pre-charging by means of resistors, an all-pole DC disconnection point for its DC terminals on its DC side (DC: direct current/direct-current voltage), a pre-charging circuit for the BEV, and a discharging circuit for the BEV. The circuit arrangement may further comprise voltage measurements on both sides of the DC disconnection point, i.e., at the DC output of a power converter having a converter circuit and at EV terminals at the input of the BEV. A DC switch of the all-pole DC disconnection point is arranged between each DC terminal and a corresponding EV terminal. The discharging circuit may comprise a discharge resistor connecting the two EV terminals. Via the discharge resistor, any residual charge in the capacitors of the BEV and its supply lines may be discharged. The pre-charging circuit can be arranged in parallel with one of the switches and, in addition to a pre-charging resistor, comprise another switch connected in series with the pre-charging resistor.

EP4057012 describes a method for in-vehicle insulation measurement in a battery electric vehicle. The insulation measurement is carried out by charging and discharging capacitors.

EP2487496 describes a method for in-vehicle insulation measurement in a battery electric vehicle. The vehicle comprises a high-voltage battery, a drive motor, a power converter arranged between the motor and the battery, and a discharging and pre-charging circuit.

### SUMMARY

In one embodiment, an electrical circuit arrangement for insulation measurement on a battery electric vehicle is connectable to a high-voltage battery of the vehicle via EV terminals. The circuit arrangement comprises an electrical power converter with AC terminals (AC: alternating current/alternating voltage) for connection to an electrical AC network and with DC terminals. A first DC terminal of the DC terminals is connectable to a first EV terminal of the EV terminals via a first DC switch, and a second DC terminal of the DC terminals is connectable to a second EV terminal of the EV terminals via a second DC switch or via a parallel circuit consisting of the second DC switch and a third DC switch. The described DC and AC switches are realized, for example, by relays. The circuit arrangement is designed and configured to connect one of the DC terminals to the corresponding EV terminal by closing one of the DC switches when the power converter is connected to the AC network, to set a DC voltage at the DC terminals by clocking the power converter, and to perform the insulation measurement on the connected vehicle.

The insulation measurement on the vehicle may, for example, include measuring insulation resistances. Insulation resistances can symbolize the vehicle's electrical resistance with respect to ground potential. The insulation measurement can, for example, determine an insulation fault if the resistance value of one of the insulation resistances between each EV terminal and ground potential, and thus the insulation resistance of the vehicle relative to ground potential, is below a minimum value.

The circuit arrangement can be part of a charging device. For safety reasons, circuit arrangements of charging devices may comprise a transformer to galvanically isolate the electric vehicle from the AC current network. Charging vehicles using a charging device is considered in standards such as IEC-61851-23, e.g., section CC.4.

Compared to charging devices with transformers, transformerless charging, i.e., charging using a charging device that does not include galvanic isolation by a transformer, would offer advantages in terms of costs, weight, and the size of the charging devices. The described transformerless circuit arrangement for insulation measurement can ensure that the current-carrying lines and the vehicle itself, and in particular its electrical storage device, i.e., the battery, are properly insulated with respect to ground potential. In addition, a so-called residual current monitor can be arranged in the connections to the AC network in order to monitor fault currents during charging and, in the event of a fault, to interrupt the charging process by opening the DC switches in the DC disconnection point and the AC switches in the AC disconnection point. The circuit arrangement described thus makes it possible to operate a transformerless charging device safely.

The vehicle's electrical storage device usually comprises several cells connected in series, wherein any insulation fault can occur at any point in this series circuit. The described circuit arrangement for insulation measurement allows insulation to be measured with such an unknown voltage source. It is advantageous that existing components of a transformerless charging device can be used for the insulation measurement. Even if small adjustments may be required, costs can be minimized while maintaining a high level of safety.

In one embodiment of the circuit arrangement, the EV terminals in the circuit arrangement are connected to one another via a discharge resistor, and the circuit arrangement is designed and configured to carry out the insulation measurement using the discharge resistor, for example, by calculating an insulation resistance on the vehicle using the discharge resistor as a component of a voltage divider.

In one embodiment of the circuit arrangement, the power converter has on its DC side a split intermediate circuit which is connected to the DC terminals, wherein the potential of the center point of the intermediate circuit has a given, i.e., substantially unchanging, relationship to ground potential when the AC side of the power converter is connected to the AC network. A DC-side DC voltage can be set, for example, by clocking the power converter, wherein “half” the DC voltage is set on each of the DC terminals. Due to the given relationship to ground of the intermediate circuit center point, this corresponds to a positive voltage on one of the DC terminals, e.g., the first DC terminal, and the same-sized negative voltage on the other DC terminal, e.g., the second DC terminal, each with respect to ground potential and taking into account the given potential of the intermediate circuit center point with respect to ground potential.

The power converter may comprise an AC/DC converter which is operable, for example, as a three-phase AC/DC converter and is configured to transfer electrical power from the electrical AC network that is connectable to the AC terminals of the power converter to the DC terminals. The power converter can be connected to the AC network via an AC disconnection point, wherein the connection is in particular initially made via pre-charging resistors, which are bridged, after pre-charging, by AC switches of the AC disconnection point.

The power transfer can be used to set the DC voltage at the DC terminals. If the circuit arrangement is part of a charging device, the electrical power transferred can be used, for example, to charge the vehicle's battery.

The insulation measurement may involve recording measured values for a first measuring voltage at the first EV terminal and recording measured values for a second measuring voltage at the second EV terminal. The measuring voltages are, in one embodiment, recorded between each EV terminal and ground potential.

In addition, the insulation measurement may involve determining one or more insulation resistance values on the vehicle using the measuring voltages. Here, the switches of the circuit arrangement are switched such that the discharge resistor acts as a voltage divider and can be used to determine the insulation resistances.

In exemplary embodiments, the circuit arrangement is designed and configured to set the DC voltage, with one of the DC terminals being connected to the corresponding EV terminal via a closed DC switch, to a first and subsequently to a second voltage value and to use first and second measured values of the measuring voltages, which are recorded at the set first and a second voltage values, to determine a first insulation resistance value for the EV terminal that is not connected to the corresponding DC terminal when setting the first and second voltage values and recording the first and second measured values, taking into account the discharge resistor.

In addition, the circuit arrangement can be designed and configured to open the DC switch that has been closed for determining the first insulation resistance value and thus to interrupt the connection between the corresponding DC terminal and the relevant EV terminal, to connect the other DC terminal to the corresponding other EV terminal by closing a different DC switch, to set the DC voltage to a third and subsequently to a fourth voltage value, and to use third and fourth measured values of the measuring voltages, which are recorded at the third and fourth voltage values, to determine a second insulation resistance value for the EV terminal that is not connected to the corresponding DC terminal when setting the third and fourth voltage values and recording the third and fourth measured values, taking into account the discharge resistor.

In embodiments, the power converter is designed in two stages and has a DC-side DC/DC converter. The DC voltage can be set at the DC terminals, for example, by cycling the DC/DC converter.

The circuit arrangement can be further designed and configured to detect a hard ground fault by means of the insulation measurement if the DC voltage cannot be set when one of the DC terminals is connected to the corresponding EV terminal. In the event of a hard ground fault at this EV terminal, e.g., in the event of a short-circuit of a line between the EV terminal and the BEV with the ground potential, the connection to ground potential is very low-resistance, so that, when a clocked connection of the corresponding DC terminal to the AC network is present via the power converter, large currents immediately flow to ground, and the DC voltage cannot be set. The insulation measurement can then be terminated when the hard ground fault is detected.

In one embodiment, the circuit arrangement can be designed and configured to charge the high-voltage battery of the vehicle. In such an embodiment, the circuit arrangement is, for example, part of a charging device or a charging station for a battery electric vehicle. For the charging process, electrical energy is transferred from the AC network to the vehicle's battery via the power converter when the first and second DC switches are closed. By using the circuit arrangement intended for charging the vehicle, a cost-effective insulation measurement can be performed.

An optional pre-charging circuit may comprise the third DC switch. The circuit arrangement may comprise a pre-charging resistor in series with the third DC switch so that the series circuit of the pre-charging resistor and the third DC switch is arranged in parallel with the second DC switch. The pre-charging resistor and the third DC switch can form the pre-charging circuit. It goes without saying that, as an alternative to a pre-charging resistor, other components such as fuses or active circuits can be used to limit the pre-charging current if required and/or to ensure that currents flowing through the third switch do not exceed a specified limit value or are interrupted if a specified limit value is exceeded. In one embodiment, the third switch is closed and the second is opened for the pre-charging process. For charging, the second switch can be closed and the third can be opened or remain closed.

In embodiments, the circuit arrangement is designed and configured to determine the insulation resistance value for the EV terminal that is not connected to the pre-charging resistor by closing the third switch and using the measured values of the measuring voltages when the third switch is closed, taking into account the discharge resistor and the pre-charging resistor. By using the pre-charging resistor for insulation measurement, even more reliable insulation measurement can be performed. In addition, the pre-charging resistor ensures that any ground currents occurring after the third switch is closed are limited in the event of a hard ground fault, regardless of which EV terminal the ground fault occurs at. If, in a subsequent step, the first switch that is not connected to the pre-charging resistor is closed, the previous check already ensures that there is no hard ground fault and, accordingly, no high currents occur.

In a method for insulation measurement on a battery electric vehicle, an electrical circuit arrangement is used which is connectable to a high-voltage battery of the vehicle via EV terminals, wherein the circuit arrangement comprises an electrical power converter with AC terminals for connection to an electrical AC network and with DC terminals. A first DC terminal is connectable to a first EV terminal via a first DC switch, and a second DC terminal is connectable to a second EV terminal via a second DC switch or via a parallel circuit with the second and a third DC switch, wherein the EV terminals are connected to one another via a discharge resistor. The method is carried out automatically, for example, by a primary control system that is connected to the vehicle and communicates therewith. The method involves:
connecting the power converter to the AC network by closing an AC disconnection point,.
connecting one of the DC terminals to the corresponding EV terminal by closing one of the DC switches,
setting a DC voltage at the DC terminals, and
performing the insulation measurement on the connected vehicle.

The method may further involve:
after setting the DC voltage to a first voltage value,
recording first measured values for a first measuring voltage at the first EV terminal and a second measuring voltage at the second EV terminal.

The first measured values are recorded when a DC voltage with the first voltage value is applied. First measured values are recorded for the first measuring voltage at the first EV terminal, and first measured values are recorded for the second measuring voltage at the second EV terminal.

The method may further involve:
after recording the first measured values of the measuring voltages,
setting the DC voltage to a second voltage value, and.
recording second measured values of the measuring voltages, and
determining a first insulation resistance value, taking into account the discharge resistor for the EV terminal that is not connected to the corresponding DC terminal when setting the first and second voltage values and recording the first and second measured values.

The second measured values are recorded when a DC voltage having the second voltage value is applied. Second measured values are recorded for the first measuring voltage at the first EV terminal, and second measured values are recorded for the second measuring voltage at the second EV terminal.

The method may further involve:
opening the DC switch that has been closed for determining the first insulation resistance value,
connecting the other DC terminal to the corresponding EV terminal by closing a different DC switch,
setting a DC voltage to a third and a fourth voltage value,
recording third and fourth measured values of the measuring voltages with the third and fourth voltage values being set, respectively, and
determining a second insulation resistance value, taking into account the discharge resistor for the EV terminal that is not connected to the corresponding DC terminal when setting the third and fourth voltage values and recording the third and fourth measured values.

The third measured values are recorded when a DC voltage having the third voltage value is applied. Third measured values are recorded for the first measuring voltage at the first EV terminal, and third measured values are recorded for the second measuring voltage at the second EV terminal.

The fourth measured values are recorded when a DC voltage having the fourth voltage value is applied. Fourth measured values are recorded for the first measuring voltage at the first EV terminal, and fourth measured values are recorded for the second measuring voltage at the second EV terminal.

In one embodiment of the method, a pre-charging resistor is arranged in series with the third DC switch so that the series circuit with the pre-charging resistor and the third DC switch is arranged in parallel with the second DC switch. The insulation resistance value for the EV terminal that is not connected to the pre-charging resistor is determined by closing the third switch and using the measured values for the measuring voltages when the third switch is closed, taking into account the discharge resistor and the pre-charging resistor.

### BRIEF DESCRIPTION OF THE FIGURES

The disclosure is further explained and described below with reference to example embodiments illustrated in the figures.

FIG. 1a shows a first example embodiment of an electrical circuit arrangement for measuring insulation,

FIG. 1b shows the first example embodiment of the electrical circuit arrangement for measuring insulation with a modified self-test circuit,

FIG. 1c shows a flow chart of a method according to one embodiment of the disclosure,

FIG. 2 shows a second example embodiment of the electrical circuit arrangement for measuring insulation, and

FIGS. 3 and 4 show examples of possible voltage curves for possible switch positions.

In the figures, identical or similar elements are denoted by the same reference signs. The representations in the drawings may not be to scale.

### DETAILED DESCRIPTION

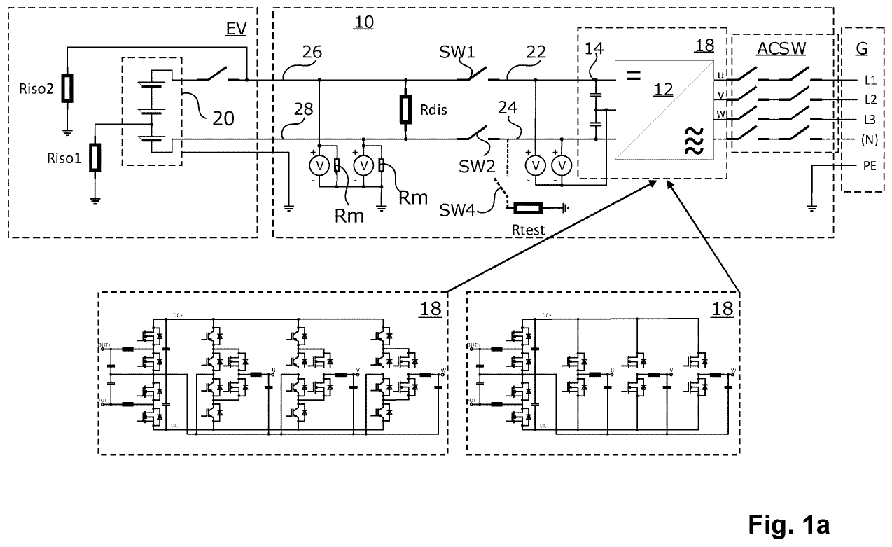

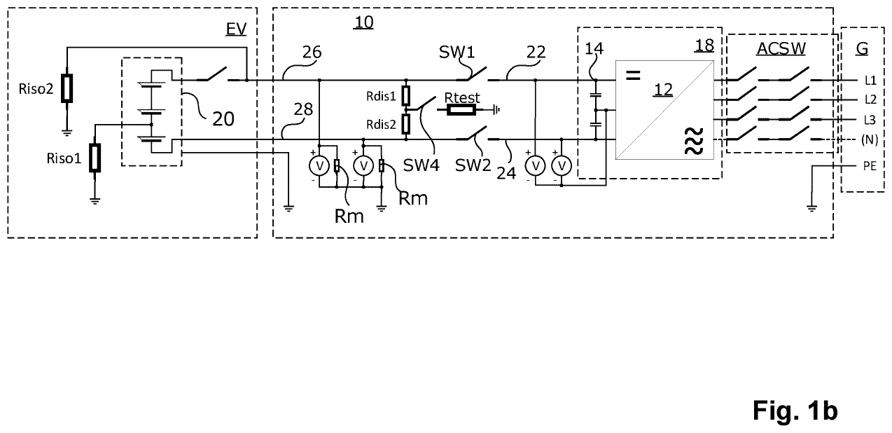

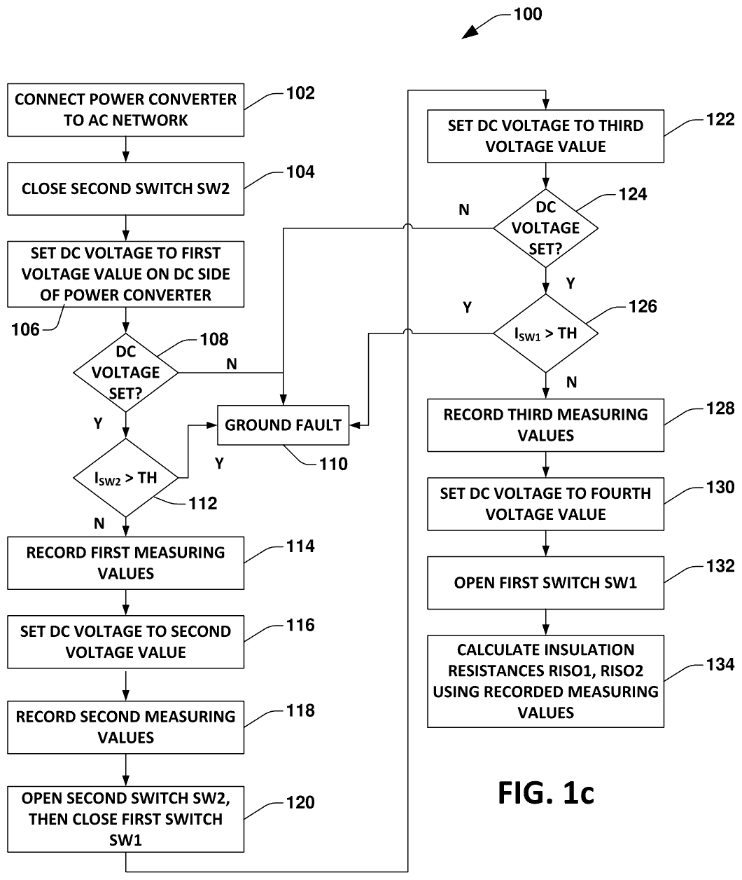

FIG. 1a shows a first embodiment of an electrical circuit arrangement 10 for insulation measurement. Such a circuit arrangement can, for example, be part of a charging device for a battery electric vehicle EV and can be usable to charge a high-voltage battery 20 of the vehicle EV.

The connection to the vehicle EV is made via a first EV terminal 26 and a second EV terminal 28. In the example shown, the first EV terminal 26 is a positive EV terminal, and the second EV terminal 28 is a negative EV terminal. In addition, FIG. 1a shows two sample insulation resistances Riso1 and Riso2, which symbolize the electrical resistance of the corresponding tapping points (here chosen at random) with respect to ground potential. An insulation fault would occur if the resistance value of one of the insulation resistances Riso1, Riso2 is below a minimum value.

As an example, for the vehicle EV, a first insulation resistance Riso1 is shown between a tapping point at the high-voltage battery of the vehicle EV near the negative potential and ground potential PE, and a second insulation resistance Riso2 is shown between a tapping point at the positive potential and ground potential PE.

In one embodiment, the battery 20 of the EV vehicle may have several cells connected in series, and any insulation fault may occur at any point in this series circuit. This is taken into account by the representation of Riso1 in FIG. 1a in that the circuit arrangement and the method for insulation measurement can also determine insulation faults that occur within the battery.

A voltmeter V is provided between the first EV terminal 26 and ground potential, and a voltmeter V is provided between the second EV terminal 28 and ground potential. The figure also shows the measuring resistors Rm of the voltmeters V by way of example.

The circuit arrangement 10 is connected to a three-phase alternating voltage (AC) network G via AC switches ACSW. The AC switches ACSW can be used to connect and disconnect the circuit arrangement to and from the AC network G in all phases. The AC network G has three phases L1, L2, L3 and optionally a neutral conductor N. The AC network G has a fixed relationship to ground potential, symbolized in FIG. 1a by a protective conductor connection PE.

The power converter 18 comprises an AC/DC converter 12 (rectifier) and a split intermediate circuit 14. In the lower part of FIG. 1a, two possible topologies are shown for the power converter 18 by way of example. The DC output of the AC/DC converter 12 comprises a first DC terminal 22 and a second DC terminal 24. In the example shown, the first DC terminal 22 is a positive DC terminal, and the second DC terminal 24 is a negative DC terminal.

A voltmeter V is provided between the first DC terminal 22 and the center point of the split intermediate circuit 14, and a voltmeter V is provided between the second DC terminal 24 and the center point of the split intermediate circuit 14. The measuring resistors of the voltmeters are not shown in the figure.

The power converter 18 can be connected to and disconnected from the EV terminals 26, 28 via an all-pole disconnector comprising a first switch SW1 and a second switch SW2. In the example shown, the first DC terminal 22 can be connected to the first EV terminal 26 via the first switch SW1, and the second DC terminal 24 can be connected to the second EV terminal 28 via the second switch SW2.

A discharge resistor Rdis is arranged between the first EV terminal 26 and the second EV terminal 28 and is used to discharge any residual charge in the capacitors of the vehicle EV. To open and close the various switches, set DC voltages, and record measuring values, and subsequently calculate one or more insulation resistances in the operation of the arrangement, one or more control circuits or processors (not shown) may be employed.

For a method (e.g., as illustrated in FIG. 1c at 100) for insulation measurement on the vehicle EV by means of the circuit arrangement 10, a connection between the power converter 18 and the AC network G is first established at 102 by closing the AC switches ACSW so that the potential of the center point of the intermediate circuit 14 approximately corresponds to the potential of the neutral conductor N of the AC network and thus to ground potential. This is even the case if there is no connection between the intermediate circuit center point and the neutral conductor N of the AC network G.

The second switch SW2 is then closed at 104, and a connection is established between the second DC terminal 24 and the second EV terminal 28. A DC voltage UDC.22, UDC.24 is then set on the DC side of the power converter 18 at 106. In one embodiment, the DC voltage UDC.22, UDC.24 is set to a first voltage value by, for example, suitably clocking the AC/DC converter 12. The DC voltage UDC.22, UDC.24 corresponds to a voltage between the first DC terminal 22 and the second DC terminal 24 when the center point of the intermediate circuit 14 is fixed. A portion UDC.22 of the DC voltage is set between the first DC terminal 22 and the center point of the divided intermediate circuit 14. Another portion UDC.24 of the DC voltage is set between the second DC terminal 24 and the center point of the divided intermediate circuit 14.

If the DC voltage UDC.22, UDC.24 cannot be set at 108 despite the clocking the AC/DC converter 12 being suitable per se, a hard ground fault is detected at 110 having a very small resistance value between the second EV terminal 28 and ground potential, for example, due to a very small Riso2. Alternatively or additionally, such a hard ground fault can be detected at 112 and 110, respectively, when a current flowing through the switch SW2 exceeds a specified limit value.

If the DC voltage UDC.22, UDC.24 can be set (Y at 108), first measuring voltage values UEV.26 and UEV.28 are recorded at 114. The measuring voltages UEV.26 and UEV.28 are voltages between EV terminals 26 and 28 and ground, respectively, which are typically not relevant to the operation of an EV charger but are employed in calculating the isolation resistance value as described below. The measuring voltage UEV.26 is recorded between the first EV terminal 26 and ground potential. The measuring voltage UEV.28 is recorded between the second EV terminal 28 and ground potential at 114.

In one embodiment, the DC voltage UDC.22, UDC.24 is then set to a second voltage value at 116 by suitably clocking the AC/DC converter 12, and second measuring voltage values UEV.26 and UEV.28 are recorded at 118.

The second switch SW2 is then opened at 120, and the connection between the second DC terminal 24 and the second EV terminal 28 is interrupted. The first switch SW1 is then closed at 120, and a connection is established between the first DC terminal 22 and the first EV terminal 28.

The DC voltage UDC.22, UDC.24 is then set to a third voltage value at 122, for example, by suitably clocking the AC/DC converter 12. The third voltage value can, for example, correspond to the first voltage value.

If the DC voltage UDC.22, UDC.24 cannot be set at 124 despite the clocking being suitable per se or generates a current that increases above a specified limit value at 126, a hard ground fault is detected at 110 having a very small resistance value between the first EV terminal 26 and ground potential, which is present, for example, due to a very small Riso1.

If the DC voltage UDC.22, UDC.24 can be set (Y at 124), third measuring voltage values UEV.26 and UEV.28 are recorded at 128. The DC voltage UDC.22, UDC.24 is then set to a fourth DC voltage UDC.22, UDC.24 at 130 by suitably cycling the AC/DC converter 12, and fourth measuring voltage values UEV.26 and UEV.28 are recorded. The fourth voltage value can, for example, correspond to the second voltage value.

The first switch SW1 is then opened 132, thereby interrupting the connection between the first DC terminal 22 and the first EV terminal 26.

In a next step, the insulation resistance Riso2 of the positive potential of the vehicle EV and the insulation resistance Riso1 of the negative potential of the vehicle EV can be calculated at 134 from the determined measuring voltage values using formulas that are known per se; see below. The calculation of the insulation resistance Riso2 of the positive potential can alternatively or additionally already be carried out after the first and second measuring voltage values UEV.26 and UEV.28 have been recorded, wherein the method can optionally be aborted at this point if the insulation resistance Riso2 already has an inadmissibly low value.

Optionally, a self-test of the insulation measuring system can be carried out, for example, before the actual insulation measurement, by connecting one of the DC terminals 22, 24 to ground potential via an optional switch SW4 and an optional self-test resistor Rtest having a known resistance value, and carrying out the method described above. During such a self-test, the switches SW1 and SW2 are open and the switch SW4 is closed, such that the method described above should determine an insulation resistance that corresponds to the known resistance value of the self-test resistor Rtest. If this is not the case, i.e., if the insulation measurement in the self-test determines an insulation resistance that deviates significantly from the known self-test resistor Rtest, the method is aborted with a corresponding error message.

FIG. 1b once again shows the first embodiment of the electrical circuit arrangement 10 for insulation measurement, wherein the discharge resistor Rdis, in contrast to FIG. 1a, consists of two separate partial resistors Rdis1, Rdis2. According to FIG. 1b, the optional self-test resistor is arranged between the connection point of the partial resistors Rdis1, Rdis2 and ground potential, wherein the connection point of the partial resistors Rdis1, Rdis2 can be connected to ground potential via a switch SW4 and the self-test resistor Rtest. During a self-test, one of the switches SW1 or SW2 and the switch SW4 are closed, so that the method described above should determine an insulation resistance composed of the known resistance values of the self-test resistor Rtest and the partial resistors Rdis1, Rdis2. If this is not the case, the method may be aborted with an error message.

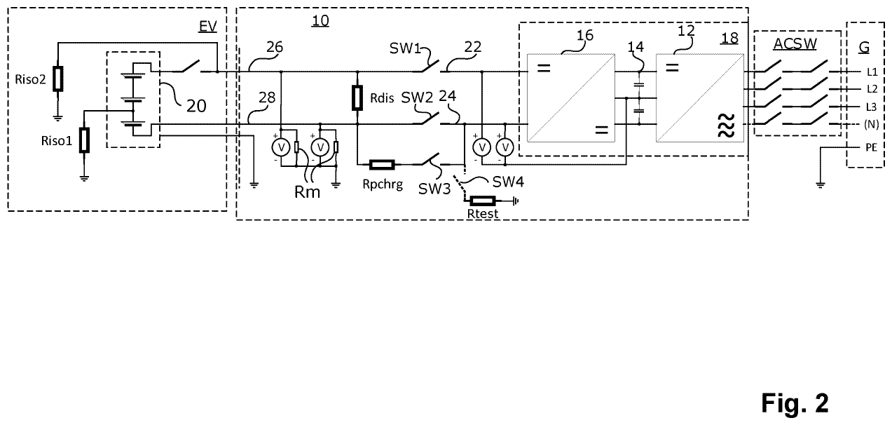

FIG. 2 shows a second embodiment of the electrical circuit arrangement 10 for insulation measurement. This embodiment can also be part of a charging device for the battery electric vehicle EV, for example, and used to charge the high-voltage battery 20 of the vehicle EV.

The connection to the vehicle EV is made via the first EV terminal 26 and the second EV terminal 28. By way of example, a first insulation resistance Riso1 and a second insulation resistance Riso2 are shown for the vehicle EV.

A voltmeter V is provided between the first EV terminal 26 and ground potential, and a voltmeter V is provided between the second EV terminal 28 and ground potential. The figure also shows the measuring resistances Rm of the voltmeters by way of example. The circuit arrangement 10 is connected to the three-phase AC network G via AC switches ACSW.

The power converter 18 comprises the AC/DC converter 12 (rectifier) with a split intermediate circuit 14 and an optional DC/DC converter 16. The AC/DC converter 12 may comprise a topology as shown by way of example in FIG. 1a. The DC output of the power converter 18 comprises the first DC terminal 22 and the second DC terminal 24.

A voltmeter V is provided between the first DC terminal 22 and the center point of the split intermediate circuit 14, and a voltmeter V is provided between the second DC terminal 24 and the center point of the split intermediate circuit 14. The measuring resistors of the voltmeters are not shown in the figure.

The power converter 18 can be connected to and disconnected from the EV terminals 26, 28 via an all-pole disconnector having a first switch SW1 and a second switch SW2. A discharge resistor Rdis is arranged between the first EV terminal 26 and the second EV terminal 28 and is used to discharge any residual charge in the capacitors of the vehicle EV.

In addition, the embodiment shown in FIG. 2 comprises an optional pre-charging circuit having a pre-charging resistor Rpchrg and a third switch SW3 arranged in series therewith. Alternatively or in addition to the pre-charging resistor Rpchrg, other components such as fuses or active circuits can be arranged in series with the switch SW3, to monitor, control, and/or limit a pre-charging current and/or any ground current.

In the illustrated example embodiment (which can follow a flow chart similar to that of FIG. 1c), the first DC terminal 22 can be connected to the first EV terminal 26 via the first switch SW1. The second DC terminal 24 can be connected to the second EV terminal 28 via the second switch SW2 and/or via the third switch SW3. In the event that the second DC terminal 24 is connected to the second EV terminal 28 via the third switch, the second DC terminal 24 is connected to the second EV terminal 28 via the pre-charging resistor Rpchrg. A current flowing from the second DC terminal 24 to the second EV terminal 28, which can be provided in particular for pre-charging capacitors in the vehicle EV, would therefore flow across the pre-charging resistor Rpchrg. Another limiting element or circuit arranged in series with the switch SW3 in addition to or as an alternative to the pre-charging resistor Rpchrg can also monitor, control, and/or limit this pre-charging current.

For the method for insulation measurement on the vehicle EV using the circuit arrangement 10, a connection between the power converter 18—in the example shown, the DC/DC converter 16 of the power converter 18—and the AC network G is first established by closing the AC switches ACSW, so that the potential of the center point of the intermediate circuit 14 approximately corresponds to ground potential. This is also the case if there is no connection between the intermediate circuit center point and the neutral conductor N of the AC network G.

The third switch SW3 is then closed, and a connection is established between the second DC terminal 24 and the second EV terminal 28 via the pre-charging resistor Rpchrg. The use of the pre-charging resistor Rpchrg has the advantage that, in the event of a possible hard ground fault, i.e., a very small resistance value between the second EV terminal 28 and ground potential, the flowing current is limited by the pre-charging resistor Rpchrg. It is also advantageous to start the method by closing the switch SW3, since excessive currents are limited by the pre-charging resistor Rpchrg. Optionally, the measurement for this exemplary embodiment can also be performed using the second switch SW2 instead of the third switch SW3.

The DC/DC converter 16 then sets a DC voltage UDC.22, UDC.24 on the DC side of the power converter 18. The DC voltage UDC.22, UDC.24 is set to the first voltage value by suitably clocking the DC/DC converter 16. The DC voltage UDC.22, UDC.24 corresponds to a voltage between the first DC terminal 22 and the second DC terminal 24 when the center point of the intermediate circuit 14 is fixed. A portion UDC.22 of the DC voltage is set between the first DC terminal 22 and the center point of the divided intermediate circuit 14, and thus between the first DC terminal 22 and ground potential. Another portion UDC.24 of the DC voltage is set between the second DC terminal 24 and the center point of the divided intermediate circuit 14, and thus between the second DC terminal 24 and ground potential.

If the desired DC voltage UDC.22, UDC.24 cannot be achieved despite the clocking being suitable per se, a hard ground fault with a very small Riso1 and/or very small Riso2 is detected, and the method is optionally aborted.

When the DC voltage UDC.22, UDC.24 is set to the first voltage value, first measuring voltage values UEV.26 and UEV.28 are recorded. The measuring voltage UEV.26 is recorded between the first EV terminal 26 and ground potential. The measuring voltage UEV.28 is recorded between the second EV terminal 28 and ground potential.

The DC voltage UDC.22, UDC.24 is then set to the second DC voltage UDC.22, UDC.24 by suitable clocking of the DC/DC converter 16, and second measuring voltage values UEV.26 and UEV.28 are recorded.

The third switch SW3 is then opened, thereby interrupting the connection between the second DC terminal 24 and the second EV terminal 28. At this point, the insulation resistance Riso2 can already be calculated from the recorded measuring voltage values, and the method can optionally be aborted if the insulation resistance Riso2 has an inadmissibly low value.

The first switch SW1 is then closed, and a connection is established between the first DC terminal 22 and the first EV terminal 28.

The DC voltage UDC.22, UDC.24 is then set to the third voltage value by suitably clocking the DC/DC converter 16. The third voltage value can, for example, correspond to the first voltage value.

If the DC voltage UDC.22, UDC.24 cannot be set despite the clocking being suitable per se, a hard ground fault with a very small resistance value is detected between the first EV terminal 26 and ground potential.

If the third voltage value can be set, third measuring voltage values UEV.26 and UEV.28 are recorded. The DC voltage UDC.22, UDC.24 is then set to the fourth DC voltage UDC.22, UDC.24 by suitably clocking the DC/DC converter 16, and fourth measuring voltage values UEV.26 and UEV.28 are recorded. The fourth voltage value can, for example, correspond to the second voltage value.

The first switch SW1 is then optionally opened, thereby interrupting the connection between the first DC terminal 22 and the first EV terminal 26.

In a following step, the equivalent source voltage Viso2 and the insulation resistance Riso2 of the positive potential of the vehicle EV as well as the equivalent source voltage Viso1 and the insulation resistance Riso1 of the negative potential of the vehicle EV can be calculated from the recorded measuring voltage values.

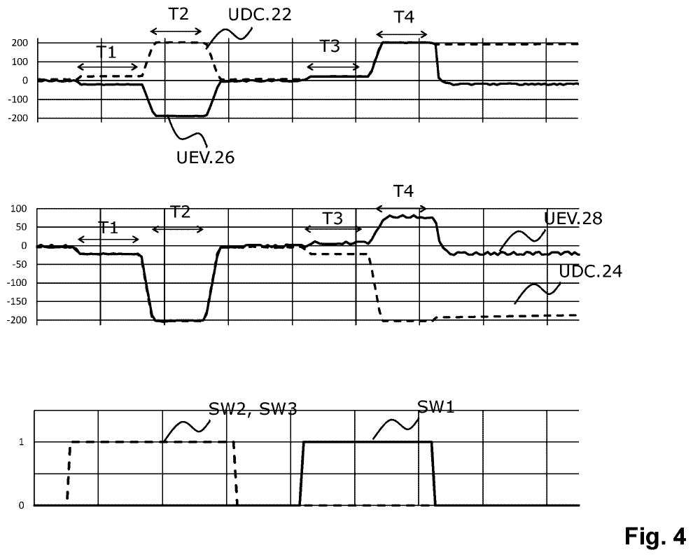

The calculation is again based upon the fact that the discharge resistor and optionally the pre-charging resistor act as a voltage divider having the insulation resistance. The calculation can be carried out in an analogous manner that is, if the components involved are known, known per se, as described in relation to FIG. 4.

Optionally, a self-test of the can be carried out, in particular before the actual insulation measurement, by connecting one of the DC terminals 22, 24 to ground potential via an optional switch SW4 and an optional self-test resistor Rtest with a known resistance value, and carrying out the method described above. During such a self-test, the switches SW1, SW2, and SW3 are open and the switch SW4 is closed, so that the method described above should determine an insulation resistance that corresponds to that of the self-test resistor Rtest. If this is not the case, i.e., if the insulation measurement in the self-test determines an insulation resistance that deviates significantly from the known resistance value of the self-test resistor Rtest, the method is aborted with a corresponding error message.

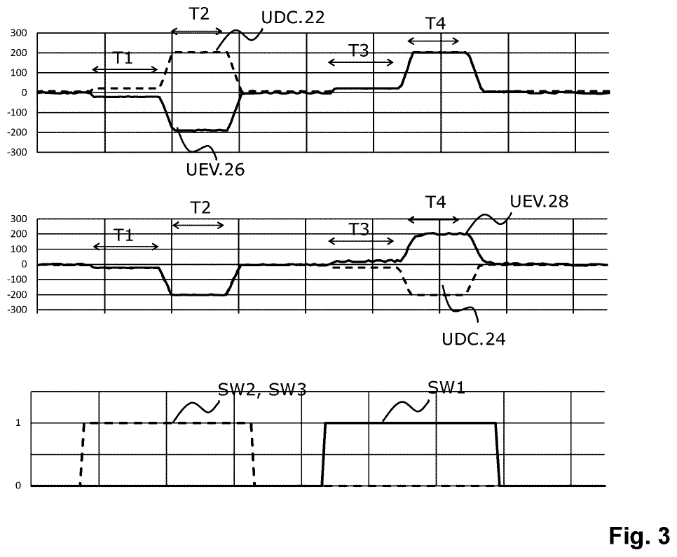

FIG. 3 and FIG. 4 show sample voltage curves for the DC voltage UDC.22, UDC.24 as well as measuring voltages UEV.26 and UEV.28. FIGS. 3 and 4 also show switch positions for the switches SW1, SW2, SW3, as can be used for the insulation measurement method described above.

FIG. 3 shows sample voltage curves for a system comprising a circuit arrangement 10, vehicle EV, and AC network G, in which the insulation on the vehicle EV is fault-free, i.e., consistently very high-resistance. FIG. 4 shows sample voltage curves for a system comprising of a circuit arrangement 10, vehicle EV, and AC network G, in which the insulation on the vehicle EV is faulty, i.e., comparatively low-resistance.

In FIGS. 3 and 4, the upper part of each figure shows voltage curves at the first, positive DC terminal 22 and the measuring voltage UEV.26 at the first, positive EV terminal. In the middle part of each figure, voltage curves at the second, negative DC terminal 24 and the measuring voltage UEV.28 at the second, negative EV terminal are plotted. In the lower part, switch positions for the first switch SW1 and the second switch SW2 for the first embodiment of FIGS. 1a and 1b are plotted. The switch position for the third switch SW3 for the second embodiment of FIG. 2 is also plotted in the lower part. A value of “1” corresponds to the switch being closed. A value of “0” corresponds to the switch being open.

FIG. 3 shows that the second switch SW2 or the third switch SW3 is closed first, and then the DC voltage is set to the first voltage value for a time period T1. The DC voltage is applied between the DC terminals 22 and 24, with half the DC voltage being applied to each of the two DC terminals 22, 24—at the positive DC terminal 22 in the positive direction and at the negative DC terminal 24 in the negative direction. Afterwards-still with the second switch SW2 or third switch SW3 closed-the second voltage value is set as the DC voltage UDC.22, UDC24 for a time period T2. It can be seen that the measuring voltages UEV26 and UEV28 recorded respectively follow the voltage on the negative DC terminal 24 quite closely. This is because, when the second or third switch SW2 or SW3 is closed and the insulation is intact, the two EV terminals 26, 28 are placed at the potential of the second, negative DC terminal 24 by means of the discharge resistor Rdis. Since the discharge resistor Rdis is small compared to the insulation resistance of the vehicle EV when the insulation is intact, the positive measuring voltage UEV.26 also follows the voltage UDC.24 applied to the negative DC terminal 24 quite closely.

After that, the DC voltage stops being set, and the second or third switch SW2 or SW3 is opened.

In the subsequent measuring cycle, the first switch SW1 is then closed, and the DC voltage is then set to the third voltage value for a time period T3. The DC voltage is applied between the DC terminals 22 and 24, with half the DC voltage being applied to each of the two DC terminals 22, 24—at the positive DC terminal 22 in the positive direction and at the negative DC terminal 24 in the negative direction. Afterwards—still with the first switch SW1 closed—the fourth voltage value is set as the DC voltage for a time period T4. It can be seen that the measuring voltages UEV26 and UEV28 recorded respectively follow the voltage on the positive DC terminal 22 quite closely. This is because, when the first switch SW1 is closed and the insulation is intact, the two EV terminals 26, 28 are placed at the potential of the first, positive DC terminal 22 by means of the discharge resistor Rdis. Since the discharge resistor Rdis is small compared to the insulation resistance of the vehicle EV when the insulation is intact, the negative measuring voltage UEV.28 also follows the voltage UDC.22 applied to the positive DC terminal 22 quite closely.

After that, the DC voltage stops being set, and the first switch SW1 is opened. This can be followed by the calculation of the insulation resistances Riso1, Riso2 using the recorded measuring voltage values.

FIG. 4 shows voltage curves for a sample fault case. In the example shown, there is specifically a finite Riso1 with a resistance value of 166 kilo-Ohms between the negative conductor at the EV terminal 28 and ground potential (cf. FIG. 1a, 1b or FIG. 2), and therefore the insulation resistance at the negative potential of the vehicle EV is faulty, i.e., too small. The resistance value of the discharge resistor Rdis is 166 kilo-Ohms in this example, too.

First of all, the second switch SW2 (exemplary embodiment according to FIG. 1a, 1b) or the third switch SW3 (exemplary embodiment according to FIG. 2) is closed, and the DC voltage is then set to the first voltage value for a time period T1. Afterwards-still with the second switch SW2 or third switch SW3 closed—the second voltage value is set as the DC voltage for a time period T2. It can be seen that the measuring voltages UEV.26 and UEV.28 recorded respectively follow the voltage on the negative DC terminal 24 quite closely. This is because, when the second or third switch SW2 or SW3 is closed and the insulation is intact, at least with respect to the positive EV terminal 26, the EV terminals 26, 28 are placed at the potential of the second, negative DC terminal 24 by means of the discharge resistor Rdis. Since the discharge resistor Rdis is small compared to the insulation resistance of the vehicle EV with respect to the positive EV terminal 26, the positive measuring voltage UEV.26 also follows the voltage UDC.24 applied to the negative DC terminal 24 quite closely.

After that, the DC voltage stops being set, and the second or third switch SW2 or SW3 is opened.

In the subsequent measuring cycle, the first switch SW1 is then closed, and the DC voltage is set to the third voltage value for a time period T3. The DC voltage is applied between the DC terminals 22 and 24, with half the DC voltage being applied to each of the two DC terminals 22, 24—at the positive DC terminal 22 in the positive direction and at the negative DC terminal 24 in the negative direction. It can be seen that the recorded measuring voltage UEV.26 follows the applied DC voltage UDC.22 exactly due to the closed first switch SW1, while the recorded measuring voltage UEV.28 follows the applied DC voltage UDC.22 much less than in FIG. 3. This is because the insulation resistance Riso1 is in series with the discharge resistor Rdis when the first switch SW1 is closed, and a ground current flows across this series circuit. The applied DC voltage UDC.22 also drops across this series circuit, which in this respect forms a voltage divider and thus lowers the potential of the positive conductor and the first, positive EV terminal 26 connected thereto. In the example according to FIG. 4, the insulation resistance Riso1 is approximately the same as the discharge resistor Rdis. Therefore, the negative measuring voltage UEV.28, which is tapped in the middle of the series circuit consisting of the discharge resistor Rdis and insulation resistor Riso1, has approximately half the value of the DC voltage UDC.22 applied to the positive DC terminal 22.

Afterwards—still with the first switch SW1 closed—the fourth voltage value is set as the DC voltage for a time period T4. It can be seen again that—due to the insulation fault—the recorded measuring voltage UEV28 follows the voltage on the positive DC terminal 22 much less than in FIG. 3 and is only about half the amount of the applied DC voltage UDC.22.

After the error is detected, the measurement can be stopped, and the first switch SW1 can be opened. In the exemplary sequence according to FIG. 4, the DC/DC converter is deactivated at the same time as the switch SW1 is opened, and the voltages UEV.26 and UEV.28 are quickly reduced via the discharge resistor Rdis. The voltages UDC.22 and UDC.24, on the other hand, decrease only slowly, especially if the power converter 18 itself does not have an internal discharge resistor.

This can be followed by the calculation of the insulation resistances Riso1, Riso2 using the recorded measuring voltage values. Without taking into account the measuring resistor Rm, an equivalent source voltage Viso2 and the insulation resistance Riso2 of the positive potential of the vehicle EV can specifically be calculated as follows:

$$Viso 2 = ( UEV \text{.28} ( T 1 ) * UEV \text{.26} ( T 2 ) - UEV \text{.28} ( T 2 ) * UEV \text{.26} ( T 1 ) ) / ( UEV \text{.28} ( T 1 ) - UEV \text{.28} ( T 2 ) - UEV \text{.26} ( T 1 ) + UEV \text{.26} ( T 2 ) ) \\ Riso 2 = Rdis * ( UEV \text{.26} ( T 1 ) - UEV \text{.26} ( T 2 ) ) / ( UEV \text{.28} ( T 1 ) - UEV \text{.28} ( T 2 ) - UEV \text{.26} ( T 1 ) + UEV \text{.26} ( T 2 ) )$$

where T1: time period having the first voltage value for UDC.22+UDC.24 and
where T2: time period having the second voltage value for UDC.22+UDC.24.

Without taking into account the measuring resistor Rm, an equivalent source voltage Viso1 and the insulation resistance Riso1 of the negative potential of the vehicle EV can specifically be calculated as follows:

$$Viso 1 = ( UEV \text{.28} ( T 3 ) * UEV \text{.26} ( T 4 ) - UEV \text{.28} ( T 4 ) * UEV \text{.26} ( T 3 ) ) / ( UEV \text{.28} ( T3 ) - UEV \text{.28} ( T 4 ) - UEV \text{.26} ( T 3 ) + UEV \text{.26} ( T 4 ) ) \\ Riso 1 = Rdis * ( UEV \text{.28} ( T 3 ) - UEV \text{.28} ( T 4 ) ) / ( UEV \text{.28} ( T 3 ) - UEV \text{.28} ( T 4 ) - UEV \text{.26} ( T 3 ) + UEV \text{.26} ( T 4 ) )$$

where T3: time period having the third voltage value for UDC.22+UDC.24 (where the third voltage value can correspond to the first voltage value) and
where T4: time period having the fourth voltage value for UDC.22+UDC.24 (where the fourth voltage value can correspond to the second voltage value).

Specifically, the following values result from the measurement according to FIG. 4:

The first measurement in the time period T1 is carried out with UDC.24=22.5 V and results in the measuring voltage values UEV.28=21.5 V and UEV.26=−20.2 V. The second measurement in the time period T2 is carried out with UDC.24=202.5 V and results in the measuring voltage values UEV.28=201.5 V and UEV.26=−189.2 V. From this, an insulation resistance Riso2=34.9 GOhm with an equivalent source voltage Uiso2=0 V is calculated.

The third measurement in the time period T3 is carried out with UDC.22=22.5 V and results in the measuring voltage values UEV.26=22.5 V and UEV.28=−10.9 V. The fourth measurement in the time period T4 is carried out with UDC.22=202.5 V and results in the measuring voltage values UEV.26=202.5 V and UEV.28=−98.2 V. From this, an insulation resistance Riso1=166 kOhm with an equivalent source voltage Uiso1=0 V is calculated.

The value of the equivalent source voltages Viso1, Viso2 corresponds here to the voltage of a voltage source connected in series with the corresponding insulation resistance Riso1, Riso2. In the example in FIG. 1a, 1b and FIG. 2, the equivalent source voltage Viso2 corresponds to 0 V, since the insulation resistance Riso2 is directly connected to the EV terminal 26, and the equivalent source voltage Viso1 corresponds to the voltage of a battery cell of the battery of the vehicle EV.

During the time periods T1 and T2, the first, positive EV terminal 26 is therefore tested, and, during the time periods T3 and T4, the second, negative EV terminal 28 is tested. It goes without saying that the order of switching operations of the switches SW1, SW2 and the associated measurements can also be changed, so that the insulation resistance of the negative EV terminal 28 can be tested first, and then the insulation resistance of the positive EV terminal 26 can be tested.

The described method can, for example, be part of a higher-level method for charging a battery 20 of a battery electric vehicle EV. The higher-level method may comprise, in particular, the following steps:
connecting the vehicle EV to the circuit arrangement 10, in particular by plugging a charging cable into the EV terminals 26, 28 of the circuit arrangement and/or into charging terminals of the vehicle EV,
communicating between the vehicle EV and the circuit arrangement 10, in particular with the exchange of suitable charging parameters,
locking the connection between the vehicle EV and the circuit arrangement 10, in particular by locking a plug connection between the charging cable and the EV terminals 26, 28 of the circuit arrangement 10 and/or between the charging cable and the charging connection of the vehicle EV,
measuring insulation on the vehicle EV in one of the variants described above, optionally with prior self-test of the insulation measurement on the optional self-test resistor Rtest by closing the optional switch SW4,
pre-charging the entire system, in particular via the closed switch SW3 and the pre-charging resistor Rpchrg, and
transferring electrical power from the AC supply network G, via the power converter 18, the closed switches SW1 and SW2, the EV terminals 26, 28, and the charging cable to the battery 20 of the vehicle EV.

What is claimed is:

1. An electrical circuit arrangement for insulation measurement on a battery electric vehicle (EV), which is configured to be connected to a high-voltage battery of the EV via EV terminals, wherein the electrical circuit arrangement comprises an electrical power converter with AC terminals for connection to an electrical AC network and with DC terminals, wherein a first DC terminal is connected to a first EV terminal via a first DC switch, and a second DC terminal is connected to a second EV terminal via a second DC switch or via a parallel circuit comprising the second DC switch and a third DC switch, wherein the electrical circuit arrangement is configured to:
connect one of the first and second DC terminals to one of the first and second EV terminals, respectively, by closing one of the first, second and third DC switches when the electrical power converter is connected to the AC network,
set a DC voltage at the first and second DC terminals by clocking the electrical power converter, and
then perform the insulation measurement on the EV when connected.

2. The electrical circuit arrangement according to claim 1, wherein the EV terminals are connected to one another via a discharge resistor, and wherein the electrical circuit arrangement is further configured to carry out the insulation measurement using the discharge resistor.

3. The electrical circuit arrangement according to claim 1, wherein the electrical power converter comprises a split intermediate circuit which is connected to the first and second DC terminals, wherein a potential of a center point of the split intermediate circuit has a fixed relationship to ground potential when the electrical power converter is connected to the AC network.

4. The electrical circuit arrangement according to claim 1, wherein the electrical power converter comprises an AC/DC converter which comprises a three-phase AC/DC converter configured to transfer electrical power from the electrical AC network when connected to the AC terminals of the electrical power converter.

5. The electrical circuit arrangement according to claim 2, wherein the insulation measurement comprises recording measured values of a first measuring voltage at the first EV terminal and recording measured values of a second measuring voltage at the second EV terminal.

6. The electrical circuit arrangement according to claim 5, wherein the insulation measurement comprises determining insulation resistance values of the EV using the first and second measuring voltages.

7. The electrical circuit arrangement according to claim 5, further configured to:
set the DC voltage with one of the first and second DC terminals connected to a corresponding one of the first and second EV terminals via a closed first, second, or third DC switch, to a first voltage value and subsequently to a second voltage value, and
use first and second measured values of the first and second measuring voltages, which are recorded at the set first and second voltage values, while taking into account the discharge resistor, to determine a first insulation resistance value for the first and second EV terminals which are not connected to the corresponding first and second DC terminals when setting the first and second voltage values and recording the first and second measured values.

8. The electrical circuit arrangement according to claim 7, further configured to:
open the first, second or third DC switch that has been closed for determining the first insulation resistance value and thus to interrupt the connection between the first or second DC terminal and the corresponding first or second EV terminal,
connect the other one of the first or second DC terminal to the corresponding other one of the first or second EV terminal by closing a different one of the first, second, or third DC switch, to set the first and second DC voltages to a third voltage value and subsequently to a fourth voltage value, and
use the third and fourth measured values of the first and second measuring voltages, which are recorded at the set third and fourth voltage values, while taking into account the discharge resistor, to determine a second insulation resistance value for the first and second EV terminals which are not connected to the corresponding first and second DC terminals when setting the third and fourth voltage values and recording the third and fourth measured values.

9. The electrical circuit arrangement according to claim 1, wherein the electrical power converter is configured in two stages and comprises a DC-side DC/DC converter, wherein the first and second DC voltages can be set at the first and second DC terminals by clocking the DC-side DC/DC converter.

10. The electrical circuit arrangement according to claim 1, further configured to detect a hard ground fault using the insulation measurement if the first and second DC voltages cannot be set and/or if a ground current above a specified limit value is detected when setting the first and second DC voltages.

11. The electrical circuit arrangement according to claim 1, further configured to charge the high-voltage battery of the EV.

12. The electrical circuit arrangement according to claim 1, further comprising a pre-charging resistor arranged in series with the third DC switch so that a series circuit comprising the pre-charging resistor and the third DC switch is arranged in parallel with the second DC switch.

13. The electrical circuit arrangement according to claim 12, wherein the pre-charging resistor and the third DC switch form a pre-charging circuit.

14. The electrical circuit arrangement according to claim 12, further configured to determine the insulation resistance value for one of the first and second EV terminals that is not connected to the pre-charging resistor by closing the third switch and using the measured values of the first and second measuring voltages when the third switch is closed, taking into account the discharge resistor and the pre-charging resistor.

15. A method for insulation measurement on a battery electric vehicle (EV) using an electrical circuit arrangement which is connected to a high-voltage battery of the EV via first and second EV terminals, wherein the electrical circuit arrangement comprises an electrical power converter with AC terminals for connection to an electrical alternating voltage (AC) network and with first and second DC terminals, wherein the first DC terminal is connected to the first EV terminal via a first DC switch, and the second DC terminal is connected to the second EV terminal via a second DC switch or via a parallel circuit comprising the second and a third DC switch, wherein the first and second EV terminals are connected to one another via a discharge resistor, the method comprising:
connecting the electrical power converter to the AC network,
connecting one of the first and second DC terminals to a corresponding one of the first and second EV terminals by closing one of the first, second and third DC switches,
setting a DC voltage across the first and second DC terminals, respectively, and performing the insulation measurement on the connected EV.

16. The method according to claim 15, further comprising:
after setting the DC voltage to a first voltage value,
recording first measured values of a first measuring voltage at the first EV terminal and a second measuring voltage at the second EV terminal.

17. The method according to claim 16, further comprising:
after recording the first measured values of the first and second measuring voltages,
setting the DC voltage to a second voltage value and recording second measured values of the first and second measuring voltages, and
determining a first insulation resistance value taking into account the discharge resistor for one of the first and second EV terminals that is not connected to the corresponding one of the first and second DC terminals when setting the first and second voltage values and recording the first and second measured values.

18. The method according to claim 17, further comprising:
opening the first, second, or third DC switch that was closed for determining the first insulation resistance value,
connecting the other one of the first and second DC terminals to the corresponding other one of the first and second EV terminals by closing a different one of the first, second, or third DC switches,
setting a DC voltage to a third and a fourth voltage value,
recording third and fourth measured values of the measuring voltages at the third and fourth voltage values, respectively, and
determining a second insulation resistance value taking into account the discharge resistor for the one of the first and second EV terminals that is not connected to the corresponding one of the first and second DC terminals when setting the third and fourth voltage values and recording the third and fourth measured values.

19. The method according to claim 15, further comprising a pre-charging resistor arranged in series with the third DC switch so that a series circuit comprising the pre-charging resistor and the third DC switch is arranged in parallel with the second DC switch, wherein the insulation resistance value for the one of the first and second EV terminals that is not connected to the pre-charging resistor is determined by closing the third switch and using the measured values of the measuring voltages when the third switch is closed, taking into account the discharge resistor and the pre-charging resistor.
